(19) United States
(12) Patent Application Publication
(10) Pub. No.: US 2016/0218185 A1
(43) Pub. Date: Jul. 28, 2016

(54) LIQUID DOPING MEDIA FOR THE LOCAL DOPING OF SILICON WAFERS

(71) Applicant: MERCK PATENT GMBH, Darmstadt (DE)

(72) Inventors: Ingo KOEHLER, Reinheim (DE); Oliver DOLL, Dietzenbach (DE); Sebastian BARTH, Darmstadt (DE)

(73) Assignee: MERCK PATENT GMBH, Darmstadt (DE)

(21) Appl. No.: 14/655,441

(22) PCT Filed: Dec. 18, 2013
(86) PCT No.: PCT/EP2013/003839

§ 371 Date: Jun. 25, 2015

(30) Foreign Application Priority Data
Dec. 28, 2012 (EP) 12008660.8
Dec. 10, 2013 (EP) 13005734.2

(51) Int. Cl. H01L 29/167; H01L 31/18; H01L 21/324; C30B 31/00; H01L 21/225

(52) U.S. Cl. CPC H01L 29/167; C30B 31/00; H01L 21/2256; H01L 21/324; H01L 31/1804

(57) ABSTRACT

The present invention relates to a novel process for the preparation of printable, low-viscosity oxide media, and to the use thereof in the production of solar cells.

The present invention relates to a novel process for the preparation of printable, low-viscosity oxide media and to the use thereof in the production of solar cells, and to the products having an improved lifetime produced using these novel media.

The production of simple solar cells or solar cells which are currently represented with the greatest market share in the market comprises the essential production steps outlined below:

### 1. Saw-Damage Etching and Texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface (nature) as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the same cell.

The above-mentioned etch solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etch solution, the etching temperature and the residence time of the wafers in the etching tank. The texturing of the monocrystalline wafers is typically carried out in the temperature range from 70-<90° C., where etching removal rates of up to 10 μm per wafer side can be achieved.

In the case of multicrystalline silicon wafers, the etch solution can consist of potassium hydroxide solution having a moderate concentration (10-15%). However, this etching technique is hardly still used in industrial practice. More frequently, an etch solution consisting of nitric acid, hydrofluoric acid and water is used. This etch solution can be modified by various additives, such as, for example, sulfuric acid, phosphoric acid, acetic acid, N-methylpyrrolidone and also surfactants, enabling, inter alia, wetting properties of the etch solution and also its etching rate to be specifically influenced. These acidic etch mixtures produce a morphology of nested etching trenches on the surface. The etching is typically carried out at temperatures in the range between 4° C. to <10° C., and the etching removal rate here is generally 4 μm to 6 μm.

Immediately after the texturing, the silicon wafers are cleaned intensively with water and treated with dilute hydrofluoric acid in order to remove the chemical oxide layer formed as a consequence of the preceding treatment steps and contaminants absorbed and adsorbed therein and also thereon, in preparation for the subsequent high-temperature treatment.

### 2. Diffusion and Doping

The wafers etched and cleaned in the preceding step (in this case p-type base doping) are treated with vapour consisting of phosphorus oxide at elevated temperatures, typically between 750° C. and <1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P2O5) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG glass has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG glass and silicon wafer, where it is reduced to phosphorus by reaction with the silicon on the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon. In this diffusion process, concentration gradients in the order of 105 form between typical surface concentrations of 1021 atoms/cm² and the base doping in the region of 1016 atoms/cm². The typical diffusion depth is 250 to 500 nm and is dependent on the diffusion temperature selected (for example 880° C.) and the total exposure duration (heating & coating phase & injection phase & cooling) of the wafers in the strongly warmed atmosphere. During the coating phase, a PSG layer forms which a typical manner has a layer thickness of 40 to 60 nm. The coating of the wafers with the PSG glass, during which diffusion into the volume of the silicon also already takes place, is followed by the injection phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed. During the injection, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG glass, and the silicon wafer. The growth of this layer is very much faster in relation to the mass flow of the dopant from the source (PSG glass), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and injection phase is, for example, 25 minutes. After this treatment, the tubular furnace is automatically cooled, and the wafers can be removed from the process tube at temperatures between 600° C. to 700° C.

In the case of boron doping of the wafers in the form of an n-type base doping, a different method is carried out, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors: crucially the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or -suppressing layers and materials).

For completeness, it should also be pointed out here that there are also further diffusion and doping technologies which have become established to different extents in the production of crystalline solar cells based on silicon. Thus, mention may be made of
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride),
gas-phase deposition of the last two,
purely thermal gas-phase deposition starting from solid dopant sources (for example boron oxide and boron nitride) and
liquid-phase deposition of doping liquids (inks) and pastes.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a flow-through furnace at temperatures between 800° C. and 1000° C., where the temperatures may be slightly increased compared with gas-phase diffusion in the tubular furnace in order to shorten the passage time. The gas atmosphere prevailing in the flow-through furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and injection of the dopant can in principle take place decoupled from one another.

### 3. Removal of the Dopant Source and Optional Edge Insulation

The wafers present after the doping are coated on both sides with more or less glass on both sides of the surface. More or less in this case refers to modifications which can be applied during the doping process: double-sided diffusion vs. quasi-single-sided diffusion promoted by back-to-back arrangement of two wafers in one location of the process boats used. The latter variant enables predominantly single-sided doping, but does not completely suppress diffusion on the back. In both cases, it is currently state of the art to remove the glasses present after the doping from the surfaces by means of etching in dilute hydrofluoric acid. To this end, the wafers are firstly re-loaded in batches into wet-process boats and with their aid dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG glass is achieved within 210 seconds at room temperature under these process conditions, for example using 2% hydrofluoric acid solution. The etching of corresponding BSG glasses is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etch solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (>25° C.<50° C.).

In the process outlined last, it has become established to carry out the so-called edge insulation sequentially at the same time, giving rise to a slightly modified process flow: edge insulation→glass etching. The edge insulation is a process-engineering necessity which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell are short-circuited via a parasitic and residue p-n junction (tunnel contact), which reduces the conversion efficiency of the later solar cell. For removal of this junction, the wafers are passed on one side over an etch solution consisting of nitric acid and hydrofluoric acid. The etch solution may comprise, for example, sulfuric acid or phosphoric acid as secondary constituents. Alternatively, the etch solution is transported (conveyed) via rollers onto the back of the wafer. The etch removal rate typically achieved in this process is about 1 μm of silicon (including the glass layer present on the surface to be treated) at temperatures between 4° C. to 8° C. In this process, the glass layer still present on the opposite side of the wafer serves as mask, which provides a certain protection against etch encroachment on this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4. Coating of the Front Side with an Antireflection Layer

After the etching of the glass and the optional edge insulation, the front side of the later solar cells is coated with an antireflection coating, which usually consists of amorphous and hydrogen-rich silicon nitride. Alternative antireflection coatings are conceivable. Possible coatings can be titanium dioxide, magnesium fluoride, tin dioxide and/or consist of corresponding stacked layers of silicon dioxide and silicon nitride. However, antireflection coatings having a different composition are also technically possible. The coating of the wafer surface with the above-mentioned silicon nitride essentially fulfils two functions: on the one hand the layer generates an electric field owing to the numerous incorporated positive charges, that can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of ˜80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. to 400° C. Alternative deposition methods can be, for example, LPCVD and/or sputtering.

### 5. Production of the Front-Side Electrode Grid

After deposition of the antireflection layer, the front-side electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content≧80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfils two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a flow-through furnace. A furnace of this type generally has a plurality of heating zones which can be activated and temperature-controlled independently of one another. During passivation of the flow-through furnace, the wafers are heated to temperatures up to about 950° C. However, the individual wafer is generally only subjected to this peak temperature for a few seconds. During the remainder of the flow-through phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. 6 and 7), which is why the term co-firing process is also used in this case.

The front-side electrode grid consists per se of thin fingers (typical number>=68) which have a width of typically 80 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3.

### 6. Production of the Back Busbars

The back busbars are generally likewise applied and defined by means of screen-printing processes. To this end, a similar silver paste to that used for the front-side metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and compacted and are sintered as already described under point 5.

### 7. Production of the Back Electrode

The back electrode is defined after the printing of the busbars. The electrode material consists of aluminium, which is why an aluminium-containing paste is printed onto the remaining free area of the wafer back by means of screen printing with an edge separation <1 mm for definition of the electrode. The paste is composed of ≧80% of aluminium. The remaining components are those which have already been mentioned under point 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom percent), where the silicon is p⁺-doped as a consequence of this injection. During cooling of the wafer, a eutectic mixture of aluminium and silicon, which solidifies at 577° C. and has a composition having a mole fraction of 0.12 of Si, deposits, inter alia, on the wafer surface.

As a consequence of the injection of aluminium into the silicon, a highly doped p-type layer, which functions as a type of mirror (“electric mirror”) on parts of the free charge carriers in the silicon, forms on the back of the wafer. These charge carriers cannot overcome this potential wall and are thus kept away from the back wafer surface very efficiently, which is thus evident from an overall reduced recombination rate of charge carriers at this surface. This potential wall is generally referred to as back surface field.

The sequence of the process steps described under points 5, 6 and 7 can, but does not have to, correspond to the sequence outlined here. It is evident to the person skilled in the art that the sequence of the outlined process steps can in principle be carried out in any conceivable combination.

### 8. Optional Edge Insulation

If the edge insulation of the wafer has not already been carried out as described under point 3, this is typically carried out with the aid of laser-beam methods after the co-firing. To this end, a laser beam is directed at the front of the solar cell, and the front-side p-n junction is parted with the aid of the energy coupled in by this beam. Cut trenches having a depth of up to 15 μm are generated here as a consequence of the action of the laser. Silicon is removed from the treated site here via an ablation mechanism or thrown out of the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is aware of solar-cell architectures with both n-type and also p-type base material. These solar cell types include PERT solar cells
PERC solar cells
PERL solar cells
PERT solar cells
MWT-PERT and MWT-PERL solar cells derived therefrom
bifacial solar cells
back surface contact cells
back surface contact cells with interdigital contacts.

The choice of alternative doping technologies, as an alternative to the gas-phase doping already described at the outset, generally cannot solve the problem of the production of regions with locally different doping on the silicon substrate. Alternative technologies which may be mentioned here are the deposition of doped glasses, or of amorphous mixed oxides, by means of PECVD and APCVD processes. Thermally induced doping of the silicon located under these glasses can easily be achieved from these glasses. However, in order to produce regions with locally different doping, these glasses must be etched by means of mask processes in order to prepare the corresponding structures out of these. Alternatively, structured diffusion barriers can be deposited on the silicon wafers prior to the deposition of the glasses in order thus to define the regions to be doped. However, it is disadvantageous in this process that in each case only one polarity (n or p) of the doping can be achieved. Somewhat simpler than the structuring of the doping sources or of any diffusion barriers is direct laser beam-supported injection of dopants from dopant sources deposited in advance on the wafer surfaces. This process enables expensive structuring steps to be saved. Nevertheless, the disadvantage of possibly desired simultaneous doping of two polarities on the same surface at the same time (co-diffusion) cannot be compensated for, since this process is likewise based on pre-deposition of a dopant source which is only activated subsequently for the release of the dopant. A disadvantage of this (post)doping from such sources is the unavoidable laser damage of the substrate: the laser beam must be converted into heat by absorption of the radiation. Since the conventional dopant sources consist of mixed oxides of silicon and the dopants to be injected, i.e. of boron oxide in the case of boron, the optical properties of these mixed oxides are consequently fairly similar to those of silicon oxide. These glasses (mixed oxides) therefore have a very low coefficient for radiation in the relevant wavelength range. For this absorption reason, the silicon located under the optically transparent glasses is used as absorption source. The silicon is in some cases heated here until it melts, and consequently warms the glass located above it. It facilitates diffusion of the dopants—and does so a multiple faster than would be expected at normal diffusion temperatures, so that a very short diffusion time for the silicon arises (less than 1 second). The silicon is intended to cool again relatively quickly after absorption of the laser radiation as a consequence of the strong transport of the heat away into the remaining, non-irradiated volume of the silicon and at the same time solidify epitactically on the non-molten material. However, the overall process is in reality accompanied by the formation of laser radiation-induced defects, which may be attributable to incomplete epitactic solidification and thus the formation of crystal defects. This can be attributed, for example, to dislocations and formation of vacancies and flaws as a consequence of the shock-like progress of the process. A further disadvantage of laser beam-supported diffusion is the relative inefficiency if relatively large areas are to be doped quickly, since the laser system scans the surface in a dot-grid process. This disadvantage naturally has less weight in the case of narrow regions to be doped. However, laser doping requires sequential deposition of the post-treatable glasses.

### OBJECT OF THE PRESENT INVENTION

Due to the doping technologies usually used in the industrial production of solar cells, namely by gas phase-promoted diffusion with reactive precursors, such as phosphoryl chloride and/or boron tribromide, it is not possible for local doping and/or locally different doping to be produced specifically on silicon wafers. On use of known doping technologies, the production of such structures is only possible through complex and expensive structuring of the substrates. During the structuring, various mask processes must be matched to one another, which makes the industrial mass production of such substrates very complex. For this reason, concepts for the production of solar cells which require such structuring have not been able to establish themselves to date. It is therefore the object of the present invention to provide a simple and inexpensive process and a medium which can be employed in this process, enabling these problems to be overcome.

### SUBJECT-MATTER OF THE INVENTION

It has been found that the problems described above can be solved by a process for the preparation of printable and low-viscosity oxide media (viscosity<500 mPas) if low-viscosity media (inks) are prepared in an anhydrous sol-gel-based synthesis by condensation of alkoxysilanes with symmetrical and asymmetrical carboxylic anhydrides by controlled gelling.

Particularly good process results are achieved if an anhydrous sol-gel-based synthesis is carried out by condensation of alkoxysilanes or alkoxyalkylsilanes with

a) symmetrical and asymmetrical carboxylic anhydrides
i. in the presence of boron-containing compounds and/or
ii. in the presence of phosphorus-containing compounds and low-viscosity doping media (doping inks) are prepared by controlled gelling.

The described process according to the invention can be carried out using alkoxysilanes or alkoxyalkylsilanes which may contain individual or different saturated or unsaturated, branched or unbranched, aliphatic, alicyclic or aromatic radicals, which may in turn be functionalised at any desired position of the alkoxide radical by heteroatoms selected from the group O, N, S, Cl, Br.

The alkoxysilanes according to the invention are silicon compounds which contain hydrolysable radicals and optionally one or two non-hydrolysable radical(s). This means that the alkoxysilanes used in accordance with the invention may contain saturated or unsaturated, branched or unbranched, aliphatic, alicyclic or aromatic radicals, individually or various of these radicals, which may in turn be functionalised at any desired position of the alkoxide radical by heteroatoms selected from the group O, N, S, Cl, Br.

Examples of hydrolysable radicals are halogen (F, Cl, Br or I, preferably Cl and Br), alkoxy (in particular C₁₋₄-alkoxy, such as, for example, methoxy, ethoxy, n-propoxy, i-propoxy and butoxy), aryloxy (in particular C₆₋₁₀-aryloxy, for example phenoxy). Particularly preferred hydrolysable radicals are alkoxy groups, in particular methoxy and ethoxy.

Examples of non-hydrolysable radicals R¹ in the sense of the invention are alkyl, in particular C₁₋₄-alkyl (such as, for example, methyl, ethyl, propyl and butyl), alkenyl (in particular C₂₋₄-alkenyl, such as, for example, vinyl, 1-propenyl, 2-propenyl and butenyl), alkynyl (in particular C₂₋₄-alkynyl, such as, for example, acetylenyl and propargyl) and aryl, in particular C₆₋₁₀-aryl, such as, for example, phenyl and naphthyl), where the groups just mentioned may optionally contain one or more substituents, such as, for example, halogen and alkoxy.

It is essential for the use according to the invention that the alkoxysilanes used can form a three-dimensional network in the sol-gel reaction, enabling the formation, on drying and compaction, of a thin layer which can be converted into a dense glass layer by temperature treatment. Alkoxysilanes which cleave off low-boiling radicals can therefore preferably be employed for the purposes of the invention. The radicals therefore preferably denote methoxy, ethoxy, n-propoxy, i-propoxy and butoxy, very particularly preferably methoxy and ethoxy. The alkoxysilanes tetraethoxysilane (TEOS) and tetramethoxysilane (TMOS) are therefore especially preferably used. However, it is also possible to use alkoxyalkylsilanes in which one or two of the radicals have the meaning alkyl, in particular C₁₋₄-alkyl, such as, for example, methyl, ethyl, propyl or butyl. In this case, preference is given to silanes which, besides the alkoxy groups, contain one or two methyl or ethyl radicals.

Although the sol-gel reaction is carried out in an anhydrous manner, a solvent or solvent mixture in suitable amount can be added to the reaction mixture, so that the reaction can be carried out at an adequate rate. Suitable solvents for this purpose are those which are themselves also formed by the condensation reaction, for example methanol, ethanol, propanol, butanol or other alcohols. Since protic solvents also result in termination of the condensation reaction, they can, however, only be added in restricted amounts. Aprotic, polar solvents, such as tetrahydrofuran, are therefore preferred. Suitable inert solvents, apart from tetrahydrofuran, are further sufficiently polar and aprotic solubilisers, such as, for example, 1,4-dioxane and dibenzyl ether, where further solvents having corresponding properties can be employed for this purpose. A suitable choice of the synthesis conditions thus enables the viscosity of the doping ink to be adjusted between a few mPas, for example 3 mPas, and 100 mPas.

This can also be achieved, inter alia, by specific termination of the condensation reaction (sol-gel reaction) by adding a sufficient amount of a protic solvent when a desired viscosity has been reached. Protic solvents of this type can be, for example, branched and unbranched, aliphatic, cyclic, saturated and unsaturated as well as aromatic mono-, di-, tri- and polyols, i.e. alcohols, and glycols, monoethers, monoacetates and the like thereof, propylene glycols, monoethers and monoacetates thereof, as well as binary, ternary, quaternary and higher mixtures of such solvents in any desired volume and/or mass mixing ratios, where the said protic solvents can be combined as desired with polar and nonpolar aprotic solvents. The term solvent is explicitly not restricted to substances which are in the liquid physical state at room temperature, such as, for example, tetramethylolpropane, 2,2-dimethyl-1,3-pentanediol, tetradecanol or similar.

The boron-containing compounds used for the preparation of boron-containing doping inks are those selected from the group boron oxide, boric acid and boric acid esters.

If phosphorus-containing compounds are used in the process according to the invention, oxide media having good properties can be obtained if the phosphorus-containing compounds are selected from the group phosphorus(V) oxide, phosphoric acid, polyphosphoric acid, phosphoric acid esters and phosphonic acid esters containing siloxane-functionalised groups in the alpha- and beta-position.

The process described enables the printable oxide media to be prepared in the form of doping media based on hybrid sols and/or gels using alcoholates/esters, hydroxides or oxides of aluminium, gallium, germanium, zinc, tin, titanium, zirconium or lead, and mixtures thereof, so that a “hybrid” sol or gel is obtained using these components. Addition of suitable masking agents, complexing agents and chelating agents in a sub- to fully stoichiometric ratio enables these hybrid sols on the one hand to be sterically stabilised and on the other hand specifically influenced and controlled with respect to their condensation and gelling rate, but also with respect to the rheological properties. Suitable masking agents and complexing agents as well as chelating agents are known to the person skilled in the art from the patent applications WO 2012/119686 A, WO2012119685 A1 and WO2012119684 A. The contents of these specifications are therefore incorporated into the disclosure content of the present application by way of reference.

In accordance with the invention, the oxide medium is gelled to give a high-viscosity, (virtually) glass-like material, and the resultant product is either re-dissolved by addition of a suitable solvent or solvent mixture. Protic and/or polar solvents are suitable for this purpose, such as, for example, propanol, isopropanol, butanol, butyl acetate or ethyl acetate or other acetic esters, ethylene glycol monobutyl ether, diethyl glycol, diethylene glycol, diethylene glycol monobutyl ether, dipropylene glycol monomethyl ether, and other glycols and ethers thereof and others, and mixtures of such solvents in which the condensation products have both adequate solubility, but also have a vapour pressure which is suitable for this purpose. In this way, a stable mixture which is stable on storage for a time of at least three months is prepared by the process according to the invention.

The doping media prepared by the process according to the invention are stable on storage, can be prepared reproducibly and are distinguished by a constant doping performance, i.e. one which is independent of the storage duration. Furthermore, media of this type can be modified by the specific addition of monofunctional or monoreactive siloxanes (capping agents), so that the storage stability of the doping media is specifically improved. Monofunctional siloxanes which are suitable for this purpose are, inter alia: acetoxytrialkylsilanes, alkoxytrialkylsilanes, such as ethoxytrimethylsilane, halotrialkylsilanes and derivatives thereof and comparable compounds. This means that addition of “capping agents” to the oxide media during preparation results in a further improvement in the stability of the oxide media obtained, making them particularly suitable for use as doping inks. These doping inks can be employed in the treatment of silicon wafers for photovoltaic, microelectronic, micromechanical and micro-optical applications.

The oxide media prepared in accordance with the invention can, depending on the consistency, i.e. depending on their rheological properties, such as, for example, their viscosity, be printed by spin or dip coating, drop casting, curtain or slot-dye coating, screen or flexographic printing, gravure, ink-jet or aerosol-jet printing, offset printing, microcontact printing, electrohydrodynamic dispensing, roller or spray coating, ultrasonic spray coating, pipe jetting, laser transfer printing, pad printing, flat-bed screen printing or rotary screen printing.

Correspondingly prepared oxide media are particularly suitable for the production of PERC, PERL, PERT, IBC solar cells BJBC or BCBJ) and others, where the solar cells have further architecture features, such as MWT, EWT, selective emitter, selective front surface field, selective back surface field and bifaciality. Furthermore, the oxide media according to the invention can be used for the production of thin, dense glass layers which act as sodium and potassium diffusion barrier in LCD technology as a consequence of thermal treatment, but in particular also for the production of thin, dense glass layers on the cover glass of a display, consisting of doped SiO₂, which prevent the diffusion of ions from the cover glass into the liquid-crystalline phase.

The present invention accordingly also relates to the novel oxide media prepared in accordance with the invention which have been prepared by the process described above and which comprise binary or ternary systems from the group SiO₂—P₂O₅, SiO₂—B₂O₃, SiO₂—P₂O₅—B₂O₃ and SiO₂—Al₂O₃—B₂O₃ and/or mixtures of higher order which arise through the use of alcoholates/esters, hydroxides or oxides of aluminium, gallium, germanium, zinc, tin, titanium, zirconium or lead during preparation. As already mentioned above, addition of suitable masking agents, complexing agents and chelating agents in a sub- to fully stoichiometric ratio enables these hybrid sols on the one hand to be sterically stabilised and on the other hand to be specifically influenced and controlled with respect to their condensation and gelling rate, but also with respect to the rheological properties. Suitable masking agents and complexing agents as well as chelating agents are known to the person skilled in the art from the patent applications WO 2012/119686 A, WO2012119685 A1 and WO2012119684 A.

The oxide media obtained in this way enable a handling- and abrasion-resistant layer to be produced on silicon wafers. This can be carried out in a process in which the oxide medium prepared by a process in accordance with the invention and printed on the surface is dried and compacted for vitrification in a temperature range between 50° C. and 750° C., preferably between 50° C. and 500° C., particularly preferably between 50° C. and 400° C., using one or more heating steps to be carried out sequentially (heating by means of a step function) and/or a heating ramp, forming a handling- and abrasion-resistant layer having a thickness of up to 500 nm.

The heat treatment is subsequently carried out on the layers vitrified on the surfaces at a temperature in the range between 750° C. and 1100° C., preferably between 850° C. and 1100° C., particularly preferably between 850° C. and 1000° C. Silicon-doping atoms, such as boron and/or phosphorus, are thus released to the substrate surface itself by silicothermal reduction of the respective oxides on the substrate surface, thereby specifically advantageously influencing the conductivity of the silicon substrate. It is particularly advantageous here that, owing to the heat treatment of the printed substrate, the dopants are transported in depths of up to 1 μm, depending on the treatment duration and time, and electrical sheet resistivities of less than 10 Ω/sqr are produced. The surface concentrations of the dopant here can usually adopt values of greater than or equal to 1*10¹⁹ to 1*10²¹ atoms/cm³. This is dependent on the nature of the dopant used in the printable oxide medium.

It has proven particularly advantageous here that the surface concentration of parasitic doping of surface regions of the silicon substrate which are not intentionally protected (masked) in advance and are not covered with the printable oxide media differs by at least two powers of ten from the doping of intentionally doped regions compared with regions which have been intentionally covered with the printable oxide media.

This result is achieved irrespective of whether the oxide medium is printed as doping medium onto hydrophilic and/or hydrophobic silicon wafer surfaces. In this connection, “hydrophilic” means a surface provided with wet-chemically applied and/or native oxide. The term “hydrophobic” in this connection means surfaces provided with silane termination.

This does not exclude the use of thin silicon layers on the silicon substrate and the printing of such silicon wafers with the doping inks according to the invention and the stimulation of the dopant to diffuse into the substrate. The effective dose of the doping occurring in the silicon substrate is thus influenced by the temperature during the treatment and its duration and indirectly by the diffusivity of the dopant in the thin oxide layer, but at the same time also by the segregation coefficients of the dopant between the silicon of the substrate and the silicon dioxide layer, which are dependent on the temperature.

In generalised terms, the process according to the invention for the production of handling- and abrasion-resistant layers on silicon and silicon wafers can be characterised in that
a. silicon wafers are printed with the oxide media as n-type doping media (for example by means of ink-jet printing), the printed-on doping media are dried, compacted and subsequently subjected to subsequent gas-phase diffusion with phosphoryl chloride, giving high doping levels in the printed regions and lower doping levels in the regions subjected exclusively to gas-phase diffusion,
   or
b. silicon wafers are printed with the oxide media as p-type oxide medium, in this case with boron-containing precursors, the printed-on doping media are dried, compacted and subsequently subjected to subsequent gas-phase diffusion with boron trichloride or boron tribromide, giving a high doping level in the printed regions and a lower doping level in the regions subjected exclusively to gas-phase diffusion,
   or
c. silicon wafers are printed in a structured manner with the oxide media as n- or p-type doping media, the printed-on doping media are dried, compacted and subsequently subjected to subsequent gas-phase diffusion with, for example, phosphoryl chloride in the case of an n-type doping medium used or with, for example, boron trichloride or boron tribromide in the case of a p-type doping medium used, enabling high doping levels to be obtained in the non-printed regions and lower doping levels to be obtained in the printed regions, to this extent keeping the source concentration of the oxidic doping media used low in a controlled manner as a consequence of the synthesis, and the glasses obtained from the doping media represent a diffusion barrier to the gas-phase diffusants transported from the gas phase to the wafer surface and deposited,
   or
d. silicon wafers are printed with the oxide media as p-type doping media, in this case with boron-containing precursors, the printed-on doping media are dried, compacted and subsequently subjected to subsequent gas-phase diffusion with boron trichloride or boron tribromide, giving high doping levels in the printed regions and lower doping levels in the regions subjected exclusively to gas-phase diffusion, and the boron skin obtained in this case on the wafer surface is subsequently removed from the wafer surface with the aid of, for example, sequential wet-chemical treatment with nitric and hydrofluoric acid,
   or
e. oxide medium deposited over the entire surface of the silicon wafer as doping medium is dried and/or compacted, and the local doping of the underlying substrate material is initiated from the compacted doping oxide medium with the aid of laser irradiation,
   or
f. oxide medium deposited over the entire surface of the silicon wafer as doping medium is dried and compacted, and the doping of the underlying substrate is initiated from the compacted doping oxide medium with the aid of suitable heat treatment, and the local doping of the underlying substrate material is augmented after this doping process with subsequent local laser irradiation, and the dopant is injected deeper into the volume of the substrate,
   or
g. the silicon wafer is printed either over the entire surface or locally with oxide media as doping media, which can be n- and p-doping media, optionally by alternating structures, the printed structures are dried and compacted and encapsulated with suitable diffusion-barrier materials, such as sol-gel-based silicon dioxide layers, sputtered or APCVD- or PECVD-based silicon dioxide, silicon nitride or silicon oxynitride layers, and the doping oxide media are brought to doping of the substrate by suitable heat treatment,
   or
h. the silicon wafer is printed either over the entire surface or locally with oxide media as doping media, which can be n- and p-doping media. This can optionally have an alternating structure sequence, such as, for example, printed n-doping oxide medium having any desired structure width, for example line width, adjacent to non-printed silicon surface, which likewise has any desired structure width. The printed structures are dried and compacted, and the wafer surface can then subsequently be provided over the entire surface with a doping medium which induces the opposite majority charge carrier polarity or printed selectively on the already printed surface. The last-mentioned doping media can be printable sol-gel-based oxidic doping materials, other printable doping inks and/or pastes, APCVD and/or PECVD glasses provided with dopants, and also dopants from conventional gas-phase diffusion and doping. The doping media arranged in an overlapping manner and having a doping action are brought to doping of the substrate by suitable heat treatment. In this connection, the in each case lowest, printed, doping oxide medium acts as diffusion barrier to the overlying oxide medium as a consequence of suitable segregation coefficients and inadequate diffusion lengths, and behaves as the doping medium which induces the contrary majority charge carrier polarity; where, in addition, the opposite side of the wafer surface can be covered with a diffusion barrier of a different type and deposited in a different way (printed, CVD, PVD), such as, for example, a silicon dioxide, silicon nitride or silicon oxynitride layer;
   or
i. the silicon wafer is printed either over the entire surface or locally with oxide media as doping media, which may be n- and p-doping media, optionally in an alternating structure sequence, such as, for example, printed n-doping oxide medium of any desired structure width, for example of any desired line width, adjacent to non-printed silicon surface, which likewise has any desired structure width. The printed structures are dried and compacted, after which the wafer surface can be provided over the entire area with a doping medium inducing the opposite majority charge carrier polarity on the already printed wafer surface, and where the last-mentioned doping media can be printable sol-gel-based oxidic doping materials or other printable doping inks and/or pastes, APCVD and/or PECVD glasses provided with dopants, but also dopants from conventional gas-phase diffusion and doping. The doping media arranged in an overlapping manner are brought to doping of the substrate by suitable heat treatment. The in each case lowest, printed, doping oxide medium will behave as diffusion barrier here to the overlying oxide medium as a consequence of suitable segregation coefficients and inadequate diffusion lengths, where the latter induces contrary majority charge carrier polarity; at the same time, the opposite wafer surface can be covered by means of a dopant source of a different type and deposited in a different manner (printable sol-gel-based oxidic doping materials, other printable doping inks and/or pastes, APCVD and/or PECVD glasses provided with dopants, and also dopants from conventional gas-phase diffusion), which may induce the same or also opposite doping to that from the lowest layer of the opposite wafer surface.

In the layer sequence characterised in this way, simple temperature treatment causes simultaneous co-diffusion from the layers formed by printed-on oxide media, with formation of n- and p-type layers or such layers exclusively of one majority charge carrier polarity, which may have different doses of dopant.

For the formation of hydrophobic silicon wafer surfaces, the glass layers formed in this process after the printing of the oxide media according to the invention, drying and compaction thereof and/or doping by temperature treatment are etched with an acid mixture comprising hydrofluoric acid and optionally phosphoric acid. The etch mixture used comprises, as etchant, hydrofluoric acid in a concentration of 0.001 to 10% by weight or 0.001 to 10% by weight of hydrofluoric acid and 0.001 to 10% by weight of phosphoric acid in a mixture.

The dried and compacted doping glasses can furthermore be removed from the wafer surface using other etch mixtures: buffered hydrofluoric acid mixtures (BHF), buffered oxide etch mixtures, etch mixtures consisting of hydrofluoric and nitric acid, such as, for example, the so-called p-etches, R-etches, S-etches or etch mixtures, etch mixtures consisting of hydrofluoric and sulfuric acid, where the above-mentioned list makes no claim to completeness.

An alternative doping technology which has already been mentioned at the outset is so-called inline diffusion. This is based on the deposition of the dopant source on the silicon wafers, after which these pass through a belt furnace of corresponding length and temperature and as a consequence of this treatment release the desired dopant to the silicon wafers. Inline diffusion is in principle the highest-performing variant of doping of silicon wafers taking into account industrial mass production of components which are manufactured in billions under considerable cost pressure from two directions. The cost pressure arises both owing to a very pronounced politically and also market-participating competitive situation. Inline diffusion can achieve industrial throughput rates that are usually between 15 and 25% above the usual throughput rates of conventional horizontal tubular-furnace plants where the inline diffusion-capable furnace systems used are generally less expensive than the typical horizontal tubular-furnace plants. Inline diffusion should thus in principle be able to generate a considerable intrinsic cost advantage over the conventionally used doping technology. Nevertheless, this advantage has hitherto virtually never been implemented efficiently in practice. The reasons for this are multifarious. A main reason consists, for example, in the deposition of the dopant source. The dopant sources in inline diffusion are usually applied wet to the wafers by means of suitable coating methods (spraying, roller coating, screen printing, etc.), dried thermally, compacted and introduced into the furnace system for the diffusion. Typical and frequently used dopant sources are dilute alcoholic (in ethanol or isopropanol) or also aqueous solutions of phosphoric or boric acid. These solutions should optimally result in a homogeneous film on the silicon surfaces in order that uniform release of the dopant to the silicon is possible. In general, homogeneous coating is not achieved, for various reasons, in particular on very rough surfaces, such as those of textured silicon wafer surfaces. Phosphoric and boric acid have an increasingly oxidic character after drying of the solution and thermal transformation into polymeric species. The oxides concerned are readily volatile and can therefore very easily contribute to autodoping of regions of the substrate which were originally not homogeneously covered with the dopant source. However, the volatility also makes it more difficult to effect spatial control of the dopant species, whose mobility not only contributes to doping on the treated surface itself (advantageous), but also to doping of wafers and surfaces thereof which have not been provided directly with the source (analogously to conventional gas-phase doping). Owing to the use of the said liquid-phase doping media, process-engineering problems, such as corrosion of the deposition units and of the furnace system, also occur. Corrosion is evident, for example, both in the case of the spray nozzles typically used and also on the wafer conveying systems. Metal ions can thus enter the dopant source, which are then injected into the silicon in the subsequent high-temperature process (cf. below).

Returning to the novel solar-cell architectures already mentioned above, a common feature of all of these is that they are in principle based on structured substrates. However, the structuring also relates to the production of regions with different doping in a sequence which is in principle as desired, but is frequently alternating, in which either regions of one polarity (n or p type) which are doped to a high and low extent or alternatively doped regions of varying polarities (n on p type and vice versa) alternate on one another. For the production of such structures, both structuring of the substrate and also deposition of thin functional layers are conceivable.

The gap between the said structuring requirements and, for example, inline diffusion is bridged inasmuch as suitable doping media can combine these two concepts if they meet at least the following requirements:
dopant sources must be printable in order to facilitate decoupling of pre-deposition and diffusion, so that dopant sources of different polarities can be deposited in small structures on the wafer surface in two successive print steps
the printable dopant sources offer the potential to facilitate adequate surface concentrations of dopants for the subsequent ohmic contacting of the doped regions
the printable dopant sources must be able to be injected into the treated silicon wafer in a co-diffusion step and thus at the same time
have low gas-phase enrichment (evaporation out of the source) in order to achieve the exclusively sharply delimiting and thus local doping
the printable dopant sources must have adequate chemical purity in their requisite formulation that is absolutely necessary for the treatment of semiconductor components.

Although the choice of liquid-phase dopant sources enables the structured application of doping sources, the doping action of these media however generally remains, as already described above, not restricted to these structured regions. Considerable entrainment (auto- and proximity-doping) of dopants from the doping source is observed, which nullifies the advantage of the structured deposition. With the solutions known to date, the doping can therefore not be restricted specifically to the deposited regions.

Known doping media additionally have a number of further significant disadvantages which are accompanied by considerable application restrictions. A typical side effect in the use of such doping media is the occurrence of a significant drop in the minority carrier lifetime of the treated silicon wafers. The minority carrier lifetime is an essential base parameter which determines the conversion efficiency of a solar cell: a short lifetime equals low efficiency and vice versa. For the person skilled in the art, everything therefore speaks against the use of the printable doping media known to date. The disadvantageous influence on the carrier lifetime is apparently caused by the raw materials used for the preparation of the doping media. In particular the assistants necessary for paste formulation, and here particularly the polymeric binders, represent a difficult-to-control source of contamination which has an adverse effect on the performance of the silicon. These assistants may contain undesired, harmful metals and metal ions, whose concentration is typically in the per thousand range. However, silicon reacts very sensitively even to metallic contamination in the range from ppb to a few ppm—in particular if the treatment of the silicon is followed by a high-temperature phase which facilitates extremely effective distribution of this harmful contamination in the volume (via diffusion and “doping”) of the silicon. Such diffusion in wafers typically occurs as a consequence of high-temperature processes, which are in turn carried out for purposes for which the doping media were deposited on the wafer surfaces. Typical and particularly harmful contamination is, for example, iron, copper, titanium, nickel and further transition metals from this group of the Periodic Table of the Elements. These metals at the same time belong to the dopants which diffuse moderately fast to very fast in silicon, so that they are able to penetrate very much deeper into the volume during the exposure duration of the doping than the desired dopants themselves, and thus impair not only the surface of the silicon, but also the entire volume thereof. Thus, in the case of iron, which is by far the most widespread contaminant, and the one generally encountered with the highest concentration, a typical theoretical diffusion depth can be expected which, under typical diffusion conditions, such as, for example, a plateau time of 30 minutes at 900° C., is easily capable of exceeding the usual silicon wafer thickness of 180 μm or less by a multiple. The consequence is a significant reduction in the above-mentioned minority carrier lifetime and, since the solar cell represents a “volume component”, the efficiency of the solar cell as a whole.

The binders added during the formulation of pastes are generally extremely difficult or even impossible to purify chemically or to free from their freight of metallic trace elements. The effort for their purification is high and, owing to the high costs, is out of proportion to the claim of the creation of an inexpensive and thus competitive, for example screen-printable, source of dopants. These assistants thus represent a constant contamination source by means of which undesired contamination in the form of on metallic species is strongly favoured.

A further, not unimportant source of contaminants is the application equipment for the application and printing of liquid doping media onto silicon wafer surfaces. Conventional liquid-phase dopants, which are used, for example, in inline diffusion, have, as already mentioned, a corrosive action on the printing equipment used, which is generally a spray device. In the case of this corrosion, which often takes place insidiously, metal ions are dissolved out of the material and transferred into the doping-ink stream and entrained thereby. In this way, the metal ions are deposited on the silicon wafer surface with the liquid-phase dopant. During subsequent drying of the liquid dopant, the metal ions present in the ink accumulate in the residue left behind. The accumulation factor is dependent on the concentration in the liquid doping medium and the dried doping layer remaining on the wafer, and thus the actual or virtual solids content in the doping ink. The accumulation factor can be between 10 and 100, i.e. in the case of a metal ion freight of 10 ppbw of any desired element, 100 ppbw to 1 ppmw remain in the dried doping layer or correspondingly may accumulate therein. The layer comprising the dopant thus represents a comparatively highly concentrated source of possible metal ions for the underlying silicon substrate. The release of the metal ions from this layer is highly dependent on the temperature and the material properties, for example the segregation coefficient of the dopant layer compared with the silicon wafer. In general, it is observed that thermal activation of the dopant layer in order to facilitate diffusion of the dopant into silicon is also capable of considerably mobilising the metal ions. It is furthermore generally true here that the diffusivity of most metal ions is many orders of magnitude higher than that of all dopants. Metal ions (3d sidegroup elements) which have diffused into the silicon, although they can form silicides and in some cases precipitate as such, are gettered and/or precipitated on oxides and oxygen clusters and grain boundaries and dislocations—in some cases also precisely because of this—have a strong recombination-active behaviour in that they induce deep flaws in the silicon electronically. These deep flaws have pronounced recombination activity for the minority charge carriers. On the other hand, since the minority charge carrier lifetime or diffusion length is one of the fundamental quality parameters of the silicon used for the production of solar cells, it plays an essential role in determining the maximum conversion efficiency that can be achieved. A very long minority charge carrier lifetime of the silicon accordingly categorically excludes the simultaneous presence of strongly recombination-active contamination in the silicon.

Surprisingly, these problems can be solved by the present invention described, more precisely by printable, low-viscosity oxide media according to the invention, which can be prepared by a sol-gel process. In the course of the present invention, these oxide media can be prepared as printable doping media by means of corresponding additives. A correspondingly adapted process and optimised synthesis approaches enable the preparation of printable doping media
which have excellent storage stability,
which exhibit excellent printing performance with exclusion of agglutination, blockages and gelling in spray and print nozzles,
which have an extremely low intrinsic contamination freight of metallic species and thus do not adversely affect the lifetime of the treated silicon wafers,
which have an adequate doping capacity in order to be able to produce even low-ohmic emitters straightforwardly on textured silicon wafers,
which can be adjusted in their content of dopants in such a way that doping profiles and the associated electrical sheet resistivities can be set and controlled very well in a broad range,
which enable very homogeneous doping of the treated silicon wafers,
whose residues can be removed very easily from the surface of treated wafers after the thermal treatment, and
which, owing to the optimised synthesis management, have excellently slight so-called autodoping behaviour.

The novel doping media can be synthesised on the basis of the sol-gel process and can be formulated further if this is necessary.

The synthesis of the doping ink can be controlled specifically by addition of condensation initiators, such as, for example, a carboxylic anhydride, with exclusion of water. In this way, the degree of crosslinking in the ink can be controlled via the stoichiometry of the addition, for example of the acid anhydride. In the case of a low degree of crosslinking, the resultant ink has low viscosity. It can therefore by processed extremely well by corresponding printing processes

Suitable printing processes can be the following:

spin or dip coating, drop casting, curtain or slot-dye coating, screen or flexographic printing, gravure or ink-jet or aerosol-jet printing, offset printing, microcontact printing, electrohydrodynamic dispensing, roller or spray coating, ultrasonic spray coating, pipe jetting, laser transfer printing, pad printing, flat-bed screen printing and rotary screen printing.

This list is not definitive, and other printing processes may also be suitable.

Furthermore, the properties of the doping media according to the invention can be adjusted specifically by addition of further additives, so that they are ideally suited for specific printing processes and for application to certain surfaces with which they may come into intense interaction. In this way, properties such as, for example, surface tension, viscosity, wetting behaviour, drying behaviour and adhesion capacity can be adjusted specifically. Depending on the requirements of the doping media prepared, further additives may also be added. These may be:
surfactants, tensioactive compounds for influencing the wetting and drying behaviour,
antifoams and deaerating agents for influencing the drying behaviour,
further high- and low-boiling polar protic and aprotic solvents for influencing the particle-size distribution, the degree of precondensation, the condensation, wetting and drying behaviour as well as the printing behaviour,
further high- and low-boiling nonpolar solvents for influencing the particle-size distribution, the degree of precondensation, the condensation, wetting and drying behaviour and the printing behaviour,
particulate additives for influencing the rheological properties,
particulate additives (for example aluminium hydroxides and aluminium oxides, silicon dioxide) for influencing the dry-film thicknesses resulting after drying as well as the morphology thereof,
particulate additives (for example aluminium hydroxides and aluminium oxides, silicon dioxide) for influencing the scratch resistance of the dried films,
oxides, hydroxides, basic oxides, alkoxides, precondensed alkoxides of boron, gallium, silicon, germanium, zinc, tin, phosphorus, titanium, zirconium, yttrium, nickel, cobalt, iron, cerium, niobium, arsenic, lead and others for the formulation of hybrid sols,
in particular simple and polymeric oxides, hydroxides, alkoxides, acetates of boron and phosphorus for the formulation of formulations which have a doping action on semiconductors, in particular silicon.

In this connection, it goes without saying that each printing and coating method makes its own requirements of the ink to be printed. Typically, parameters which are to be set individually for the particular printing method are those such as the surface tension, the viscosity and the overall vapour pressure of the ink.

Besides their use as doping source, the printable media can be used as scratch-protection and corrosion-protection layers, for example in the production of components in the metal industry, preferably in the electronics industry, and in this case in particular in the manufacture of microelectronic, photovoltaic and microelectromechanical (MEMS) components. Photovoltaic components in this connection are taken to mean, in particular, solar cells and modules. Applications in the electronics industry are furthermore characterised by the use of the said inks and pastes in the following areas, which are mentioned by way of example, but are not comprehensive: manufacture of thin-film solar cells from thin-film solar modules, production of organic solar cells, production of printed circuits and organic electronics, production of display elements based on technologies of thin-film transistors (TFTs), liquid crystals (LCDs), organic light-emitting diodes (OLEDs) and touch-sensitive capacitive and resistive sensors.

The present description enables the person skilled in the art to apply the invention comprehensively. Even without further comments, it is therefore assumed that a person skilled in the art will be able to utilise the above description in the broadest scope.

If there is any lack of clarity, it goes without saying that the publications and patent literature cited should be consulted. Accordingly, these documents are regarded as part of the disclosure content of the present description.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present application to these alone.

Furthermore, it goes without saying to the person skilled in the art that, both in the examples given and also in the remainder of the description, the component amounts present in the compositions always only add up to 100% by weight, mol-% or % by vol., based on the entire composition, and cannot exceed this, even if higher values could arise from the percent ranges indicated. Unless indicated otherwise, % data are therefore regarded as % by weight, mol-% or % by vol.

The temperatures given in the examples and description as well as in the claims are always in ° C.

### EXAMPLES OF LOW-VISCOSITY DOPING MEDIA

### Example 1

5.8 g of ortho-phosphoric acid which has been dried in a desiccator are dissolved in 10 g of acetic anhydride by brief heating in a 250 ml round-bottomed flask. This solution is slowly added dropwise with stirring to 19.4 g of tetraethyl orthosilicate. The ethyl acetate formed is distilled off with stirring and constant warming at 100° C. In order to adjust the viscosity, a further 1 10 g of acetic anhydride can be added. In order to terminate the reaction, 25-50 g of a protic solvent are subsequently added. This solvent can be selected as desired from the group mentioned for this purpose in the description.

It can be shown by a ³¹P-NMR investigation of the resultant ink that the phosphorus species are bound into the SiO₂ network.

The doping media prepared by this process are stable on storage.

FIG. 1 shows a ³¹P-NMR measurement of an ink resulting in accordance with Example 1. The chemical shift of free phosphoric acid is 0 ppm and cannot be detected in this example. The phosphoric acid must therefore be strongly bound into the SiO₂ matrix.

### Example 2

A number of doping-media batches, following Example 1 outlined above, are prepared, and in each case a polished p-type silicon wafer is printed with the doping inks after HF cleaning by means of spin coating (2000 rpm for 30 s). After subsequent baking for 2 minutes on a hotplate (100° C.), diffusion at 900° C. for 8 minutes results in a sheet resistivity of 50 Ω/sqr. FIG. 2 shows a resultant ECV profile of the emitter which has diffused in.

FIG. 2 shows the doping profiles of the doping experiments with doping media prepared in a repeatable manner. The doping media have a reproducible doping action.

### Example 3

A polished p-type silicon wafer is, after HF cleaning, printed with a phosphorus-doped SiO₂ matrix in accordance with Example 1 by means of spin coating (2000 rpm for 30 s). After subsequent baking for 2 minutes on a hotplate (100° C.), diffusion at 900° C. for 8 minutes results in a sheet resistivity of 50 Ω/sqr. FIG. 3 shows a resultant ECV profile of the emitter which has diffused in and in addition the behaviour of auto- and/or proximity doping. The proximity is investigated in accordance with an arrangement of silicon wafers corresponding to FIG. 3. It can be seen from the two doping profiles (source vs. sink) that the doping action on the source and sink differ by a factor >1000 with respect to the surface concentrations determined in each case.

FIG. 3 shows the ECV profiles of the doping experiments described above.

### Example 4

A textured p-type silicon wafer is, after HF cleaning, printed with a phosphorus-doped SiO₂ matrix in accordance with Example 1 with isopropanol or a comparable solvent, defined via vapour pressure and/or Hansen solubility parameter, ethyl acetate or a comparable solvent, defined via vapour pressure and/or Hansen solubility parameter, and butanol or a comparable solvent, defined via vapour pressure and/or Hansen solubility parameter, as solvent (weight ratio 1:1:0.25) by means of spray coating. After subsequent baking for 2 minutes on a hotplate (100° C.), diffusion at 900° C. for 15 minutes results in a sheet resistivity of 40-50 Ω/sqr. In order to assess the homogeneity of the applied layer, FIG. 3 shows a scanning electron photomicrograph of the applied layer after diffusion.

FIG. 4 shows a scanning electron photomicrograph (50,000 times magnification) of the diffusion layer applied to a pyramid of an alkaline-textured (100) wafer. The homogeneous coverage of the surface by the sprayed-on PSG layer is readily evident. The measured layer thickness is 44 nm.

A further doping experiment with an ink in accordance with Example 1 using the coating conditions described above, but using a longer diffusion duration, 20 minutes, gives an average sheet resistivity of 28 Ω/sqr with a surface concentration of 8*10²⁰ atoms/cm².

FIG. 5 shows the sheet-resistance distribution (top right) on an ink deposited over the entire surface with doping medium in accordance with Example 1. The ECV profile (bottom left) gives a typical measurement point on the sample.

### Example 5

A textured p-type silicon wafer is, after HF cleaning, printed locally with a phosphorus-doped SiO₂ matrix in accordance with Example 1, with dipropylene glycol monomethyl ether as solvent, by means of ink-jet printing. After subsequent baking for 2 minutes on a hotplate (100° C.), diffusion at 900° C. for 15 minutes results in a sheet resistivity of 40-50 Ω/sqr. In order to assess the expulsion of phosphorus gas from the printed PSG, FIG. 4 shows a resultant ECV profile of the emitter which has diffused in and a measurement 1 mm alongside the printed point. The surface concentrations of the two regions differ by a factor 100.

FIG. 6 shows the ECV profile of the emitter which has diffused in and a reference measurement 1 mm alongside the printed point.

### Example 6

A polished p-type silicon wafer is, after HF cleaning, printed on both sides with a phosphorus-doped SiO₂ matrix in accordance with Example 1 by means of spin coating (2000 rpm for 30 s). After respective baking for 2 minutes on a hotplate (100° C.), diffusion at 900° C. for 8 minutes results in a sheet resistivity of 30 Ω/sqr.

FIG. 7 shows the lifetime of a market-accompanying doping ink after doping under similar conditions (p-type wafer, polished on one side, conductivity 1-10 Ω⁻¹*cm⁻¹) in order to achieve a comparable sheet resistivity of 50 Ω/sqr, determined via QSSPC measurement (quasi-stationary photoconductivity measurement) and read out at an injection density of 1*10¹⁵ minority charge carriers/cm³. The lifetime is 130 μs. The lifetime of a comparable, but untreated, i.e. undoped, reference wafer is 320 μs. The wafers have been passivated by wet-chemical methods by means of the methanol/quinhydrone method.

FIG. 7 shows a comparative lifetime measurement of a p-type wafer doped with a commercially available doping ink against a comparable reference wafer.

FIG. 8 shows by way of comparison the lifetime of a p-type wafer in accordance with the procedure outlined above using a doping ink in accordance with Example 1 compared with the lifetime of a commercially available doping ink. The lifetime of the wafer, coated with an ink according to the invention, has a value of 520 μs and is thus a factor of four longer than that of the competing batch. The increase in the lifetime is attributable to the optimised synthesis method using very pure chemicals and adequate pre-purification of the solvents used.

FIG. 8 shows the comparative lifetime measurement of a wafer produced by the optimised synthesis process and treated using adequately pre-treated solvents compared with a wafer after doping with a commercially available doping ink. The additional increase in the lifetime of the wafer treated with the doping ink prepared in accordance with the invention compared with that of the reference wafer is attributable to the additional getter effect (sink for contaminants) as a consequence of diffusion with phosphorus. By contrast, the commercially available doping ink functions as source of contaminants.

### Example 7

### Comparative Example

In a comparative experiment, a doping ink is prepared in accordance with the following conditions: 67.3 g of ethanol, 54.2 of ethyl acetate, 13.3 g of acetic acid, 32.5 g of tetraethyl orthosilicate are weighed out into a 250 ml flask, mixed well, and 6.7 g of water are added. 1.7 g of phosphorus pentoxide (P4010) are dissolved in this mixture, and the mixture is warmed under reflux for 24 h. After synthesis of the doping ink, the latter is stored in a refrigerator at +8° C. and used at certain time intervals for the doping of silicon wafers. To this end, the ink is in each case applied to a p-type wafer which has been polished on one side having a conductivity of 1-10 Ω*cm by spin coating (2000 rpm, for 30 s). The wafer is subsequently dried on a hotplate at 100° C. for 2 minutes and then sent to doping in a conventional muffle furnace at 900° C. for 20 minutes. After diffusion, the PSG glass formed is removed from the wafer surface by means of dilute hydrofluoric acid (˜2%), and the sheet resistivity is determined by means of four-point measurement. The doping action of the doping ink prepared by this process demonstrates a pronounced time dependence of the doping action to be observed. There is a proportional correlation: the doping capacity of the doping medium decreases with increasing storage duration thereof. The doping medium exhibits no long-term storage stability.

FIG. 9 shows the doping potential of a doping medium prepared in accordance with Example 6 plotted against the storage duration: the sheet resistivity to be achieved as a function of the doping medium storage duration with cooling.

The observation explained above is independent of the sequence of addition of the phosphorus pentoxide: initial introduction and subsequent addition of the solvents or initial introduction of the solvents and then use of phosphorus pentoxide and subsequent addition of the organosilicon compound, the acetic acid and the water, etc., always produces the same behaviour. The observation is furthermore independent of the type of phosphorus compound and the sequence in which this is added: aqueous or crystalline phosphoric acid, polyphosphoric acid, phosphoric acid esters, such as, for example, mono-, di- and tributyl phosphate, or phosphorus pentoxide itself.

Furthermore, the observations explained above are independent of the choice of solvents used. Experiments with propanol, isopropanol, butanol, ethylene glycol monobutyl ether, diethyl glycol, diethylene glycol, diethylene glycol monobutyl ether, further glycols and ethers thereof, mixed with simple alcohols or ethyl acetate or butyl acetate or further suitable solvents repeatedly give a comparable result as shown in FIG. 9.

The use of inorganic and organic phosphonic acids results in the same observations, with the exception that doping media of this type, with compensation for the differing relative proportions by weight of phosphorus present in the precursor substances, have an even lower doping action than those prepared using pentavalent phosphorus sources. Phosphonic acids of this type can be, for example: phosphonic acid, dibutyl phosphonate, diethyl triethoxysilylethylphosphonate and etidronic acid.

“Post-doping” of pre-condensed polysiloxanes prepared by the process described above, apart from the addition of phosphorus pentoxide, with aqueous and/or crystalline phosphoric acid and also with phosphorus pentoxide generally results in rapid gelling (within a few hours) of the doping solution prepared in this way. Solutions of this type prove to have inadequate storage stability in accordance with the industrial demands made of such media.

### Example 8

3.6 g of boric acid which has been pre-dried in a desiccator are dissolved in 12.5 g of tetrahydrofuran at 70° C. with stirring in a 250 ml round-bottomed flask. 12.3 g of acetic anhydride are added with stirring, and 19.4 g of tetraethyl orthosilicate are subsequently slowly added dropwise. When all the tetraethyl orthosilicate has been added, the solution is warmed to 100° C. and freed from volatile solvents. 55 g of a protic solvent are subsequently added (suitable solvents are shown in the description). Alternatively, a solvent mixture in accordance with Example 4 can be added in corresponding amount. The resultant mixture is kept under reflux until a completely clear solution has formed.

The doping ink can alternatively also be synthesised using a mixture of tetraethyl orthosilicate and aluminium isobutoxide. The partial substitution of tetraethyl orthosilicate by aluminium isobutoxide may make it necessary to add a sub-stoichiometric amount of complexing ligands, such as, for example, those of acetylacetone, salicylic acid, 2,3-dihydroxy- and 3,4-dihydroxybenzoic acid or mixtures thereof.

### Example 9

A polished n-type silicon wafer is, after HF cleaning, printed on one side with a boron-doped SiO₂ matrix in accordance with Example 8 by means of spin coating (2000 rpm for 30 s). After baking on a hotplate (100° C.) for 2 minutes, diffusion in a muffle furnace at 1000° C. for 30 minutes results in a sheet resistivity of 30 Ω/sqr. An alternative diffusion in a tubular furnace at 950° C. for 30 minutes in a stream of nitrogen gives a sheet resistivity of 105 Ω/sqr.

FIG. 10 shows the curve of the doping potential (ECV profile) of a doping medium prepared in accordance with Example 8 (red=boron concentration, blue=base doping (P)). The doping was carried out in a muffle furnace at 1000° C. for 30 minutes.

FIG. 11 shows the curve of the doping potential (ECV profile) of a doping medium prepared in accordance with Example 8 (red=boron concentration, blue=base doping (P)). The doping was carried out in a tubular furnace at 950° C. for 30 minutes in a nitrogen atmosphere.

### Example 10

83 g of crystalline phosphoric acid which has been pre-dried in a desiccator are weighed out into a stirred apparatus, and 150 g of tetrahydrofuran are added. The mixture obtained is brought to reflux with the aid of an oil bath (80° C.). 100 g of acetic anhydride are rapidly added dropwise to the boiling mixture from an attached dropping funnel. 190 g of tetraethyl orthosilicate (TEOS) are slowly added dropwise to this mixture to the mixture initially introduced in the apparatus from a further dropping funnel with vigorous stirring. When the addition of the tetraethyl orthosilicate is complete, the temperature of the oil bath is increased to 120° C., and the mixture is left at this temperature for one hour with vigorous stirring. The reaction is subsequently quenched using a solvent mixture consisting of 150 g of ethyl acetate, 600 g of isopropanol and 150 g of ethoxypropanol and refluxed for a further 60 minutes. The doping ink enables homogeneous spray coating of silicon wafers.

The content of acetic anhydride in the reaction mixture in accordance with this Example 10 can be varied. To this end, it has proven advantageous to use weights of between 90 g and 380 g of the reactant. The crosslinking of the oxidic network can be controlled via the amount of acetic anhydride added, the amount of tetrahydrofuran present in the reaction mixture, the warming duration of the reaction mixture at 120° C. and also the temperature of warming. The warming duration after all the reactants have been added can be between 30 minutes and 240 minutes. Suitable inert solvents, apart from tetrahydrofuran, are further sufficiently polar and aprotic solubilisers, such as, for example, 1,4-dioxane and dibenzyl ether, where further solvents having corresponding properties can be employed for this purpose. A suitable choice of the synthesis conditions mentioned above enables the viscosity of the doping ink to be adjusted between a few mPas, for example 3 mPas, and 100 mPas. The stabilisation of the doping ink can be achieved after its synthesis by means of capping agents which have already been described. To this end, the ink is advantageously immediately provided, during quenching using one or more of the said solvents, with a suitable capping agent, such as, preferably, ethoxytrimethylsilane. It has proven advantageous here to use 10 ml to 50 ml of the capping material, in this case ethoxytrimethylsilane. For the preparation of doping media which are very highly capable of ink-jet printing, it has proven advantageous to use other solvents for quenching the reaction mixture. Suitable solvents are mentioned in connection with Example 5. It goes without saying that all the doping-ink syntheses described can also be carried out with boron-containing precursors substituting for the phosphorus precursor.

### LIST OF FIGURES

FIG. 1: ³¹P-NMR profile of an ink in accordance with Example 1. The chemical shift of free phosphoric acid is 0 ppm and cannot be detected in this example.

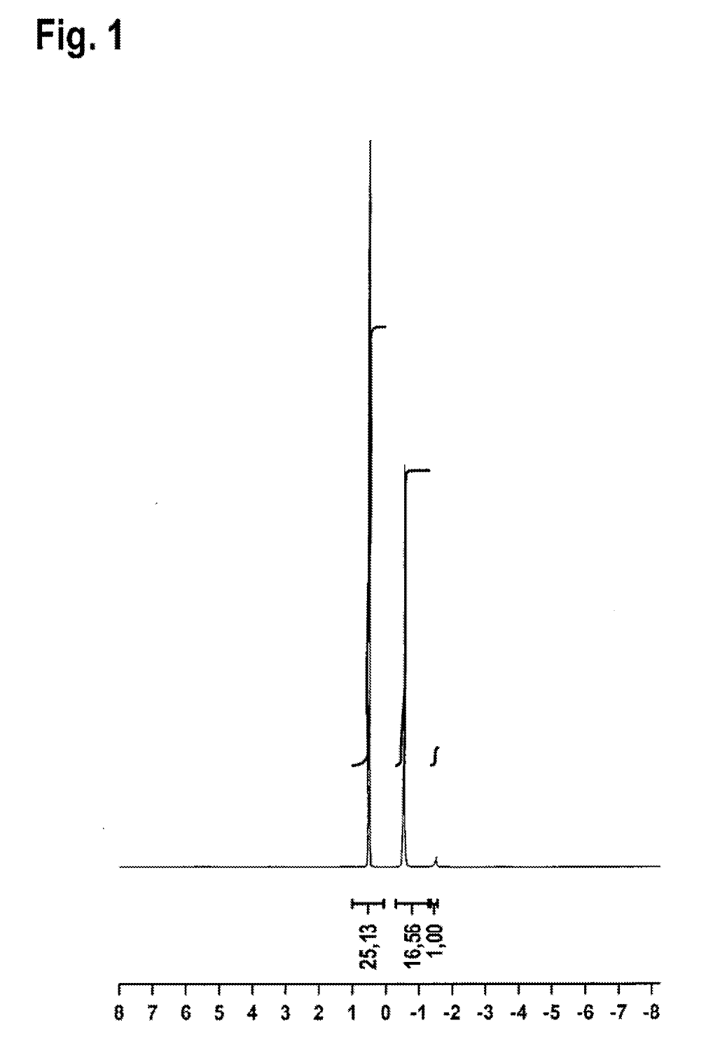

FIG. 2: Doping profiles of doping experiments in accordance with Example 2 with reproducible doping media and constant doping action.

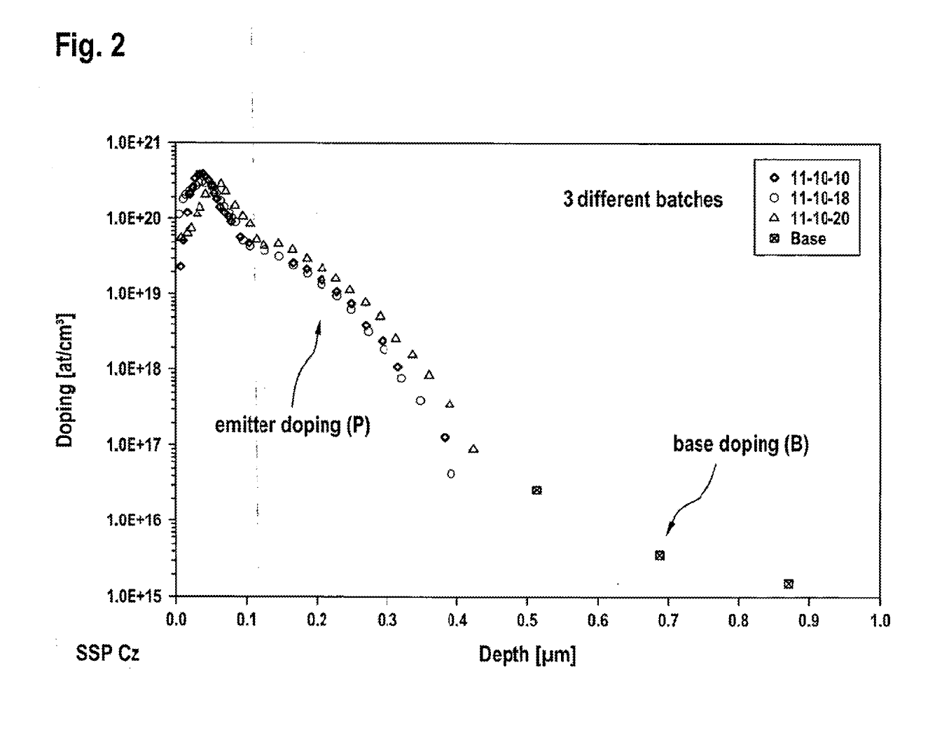

FIG. 3: ECV profiles of doping experiments in accordance with Example 3.

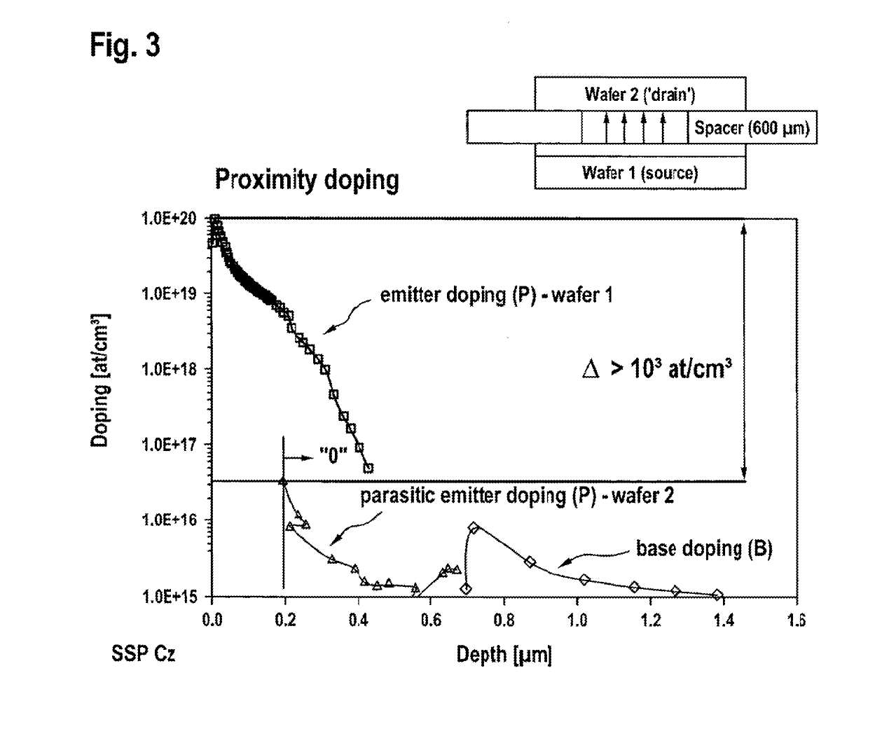

FIG. 4: Scanning electron photomicrograph (50,000 times magnification) of a diffusion layer applied to a pyramid of an alkaline-textured (100) wafer. The homogeneous coverage of the surface by sprayed-on PSG layer is readily evident. The measured layer thickness is 44 nm.

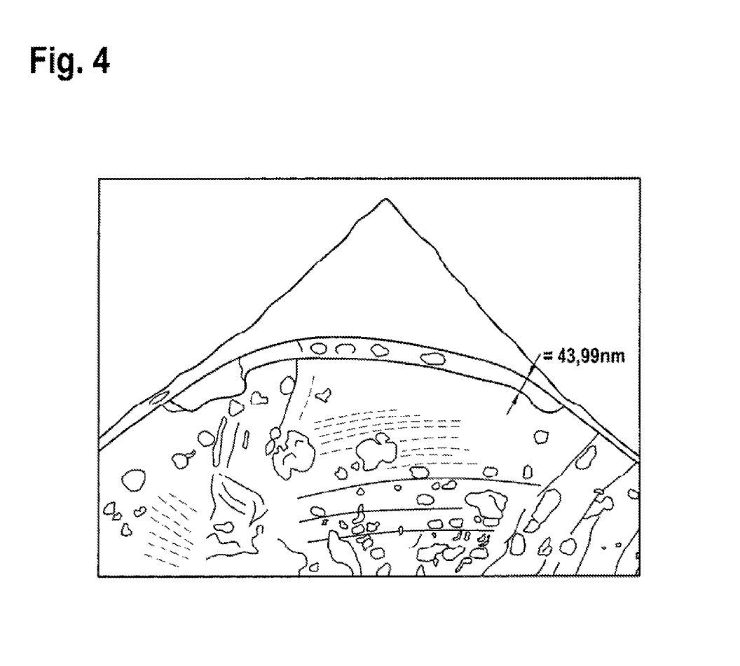

FIG. 5: Sheet-resistance distribution (top right) on a wafer treated over the entire surface with doping medium in accordance with Example 1. The ECV profile (bottom left) corresponds to a typical measurement point on the sample.

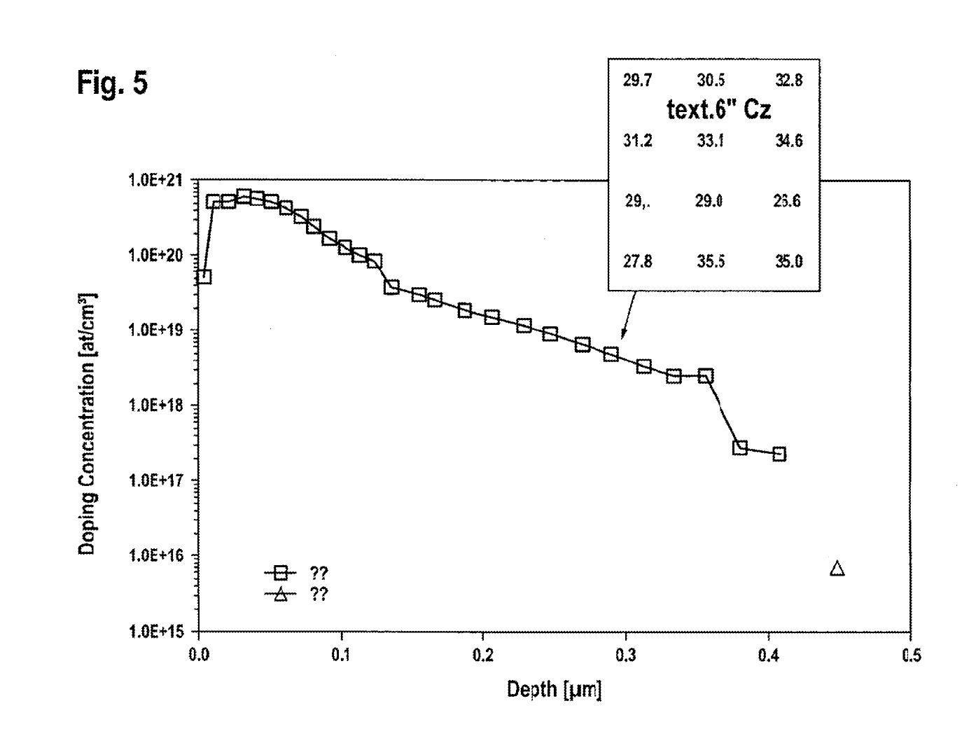

FIG. 6: ECV profile of an emitter which has diffused in and a reference measurement 1 mm alongside the printed point.

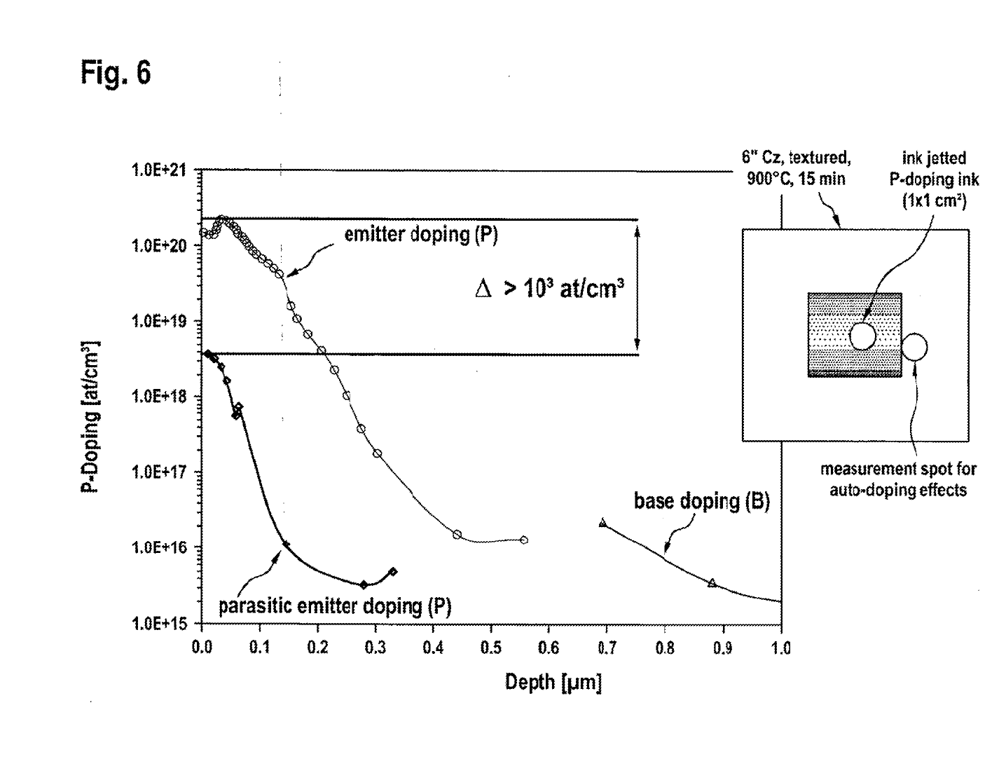

FIG. 7: Comparative lifetime measurement of a p-type wafer doped with a commercially available doping ink against a comparable reference wafer.

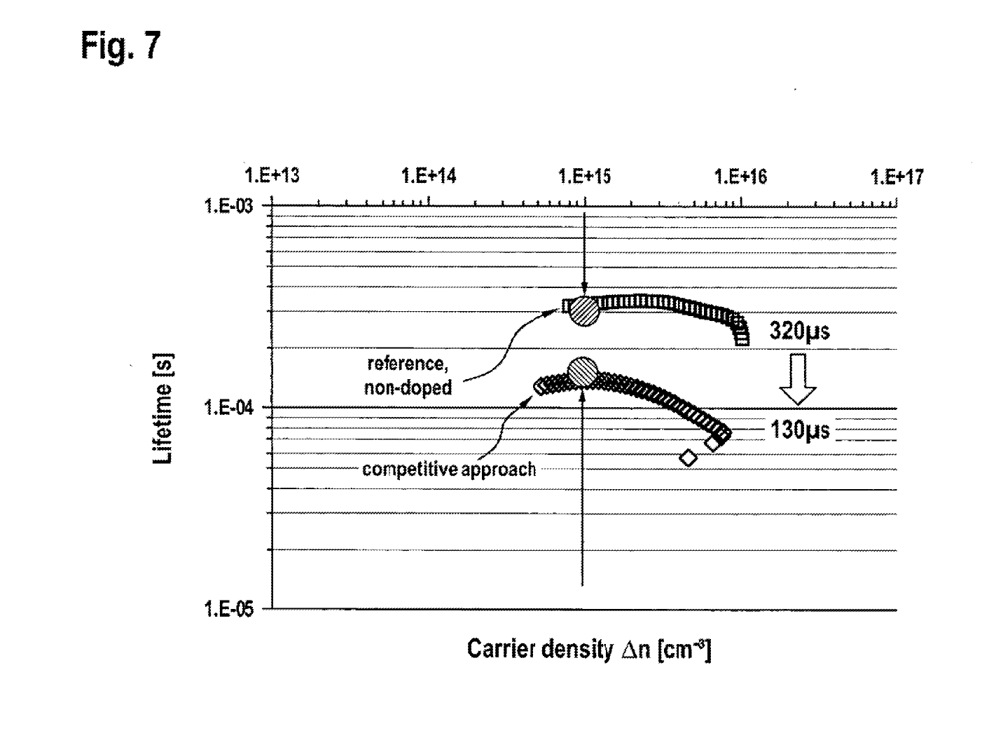

FIG. 8: Comparative lifetime measurement of a wafer produced by the optimised synthesis process and treated using adequately pre-treated solvents compared with a wafer after doping thereof with a commercially available doping ink.

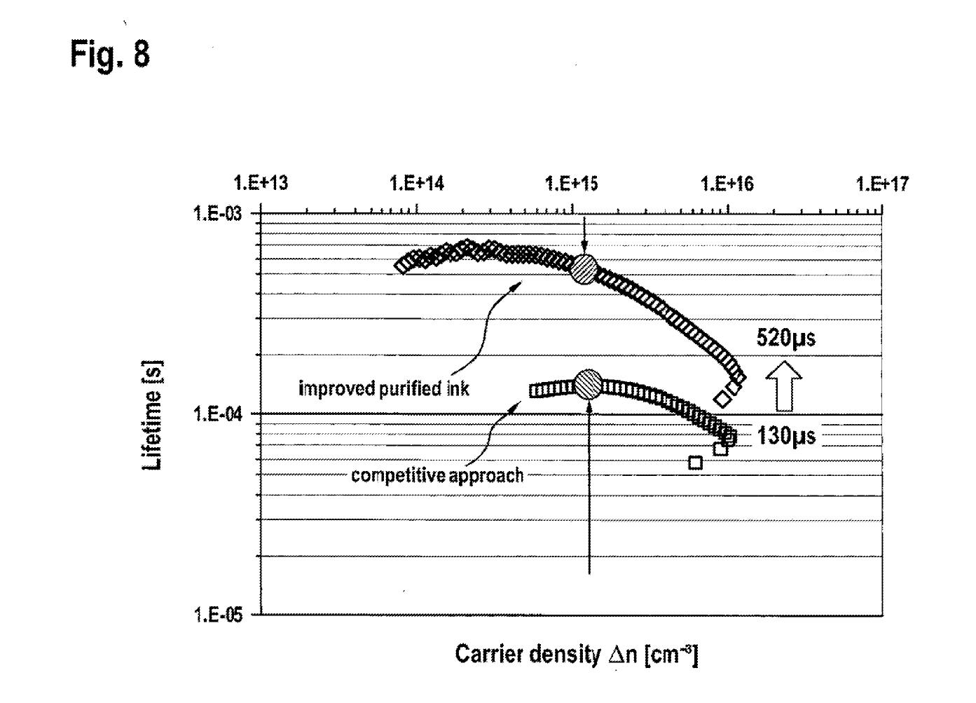

FIG. 9: Doping potential of a doping medium prepared in accordance with Example 6; sheet resistivity as a function of the doping medium storage duration with cooling.

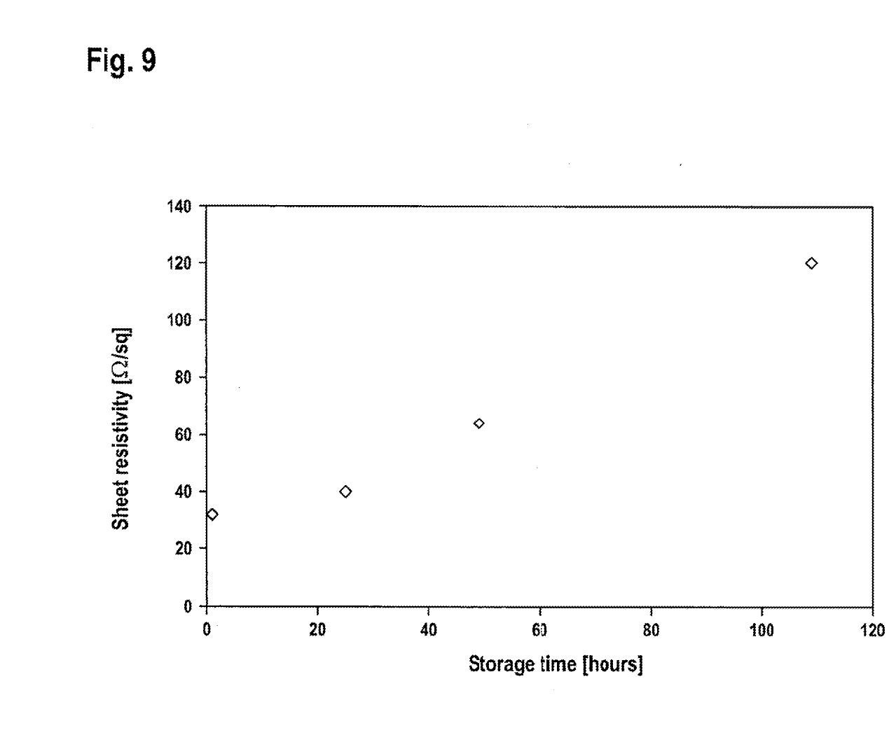

FIG. 10: Doping potential (ECV profile) of a doping medium prepared in accordance with Example 8 (red=boron concentration, blue=base doping (P)); doping in a muffle furnace at 1000° C. for 30 minutes.

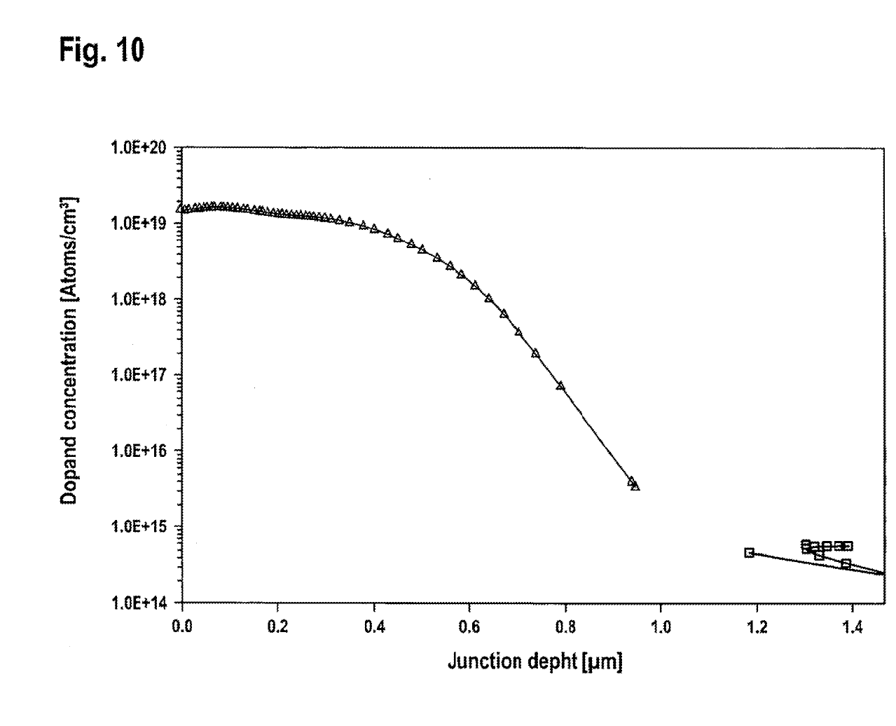

FIG. 11: Doping potential (ECV profile) of a doping medium prepared in accordance with Example 8 (red=boron concentration, blue=base doping (P)); doping in a tubular furnace at 950° C. for 30 minutes in a nitrogen atmosphere.

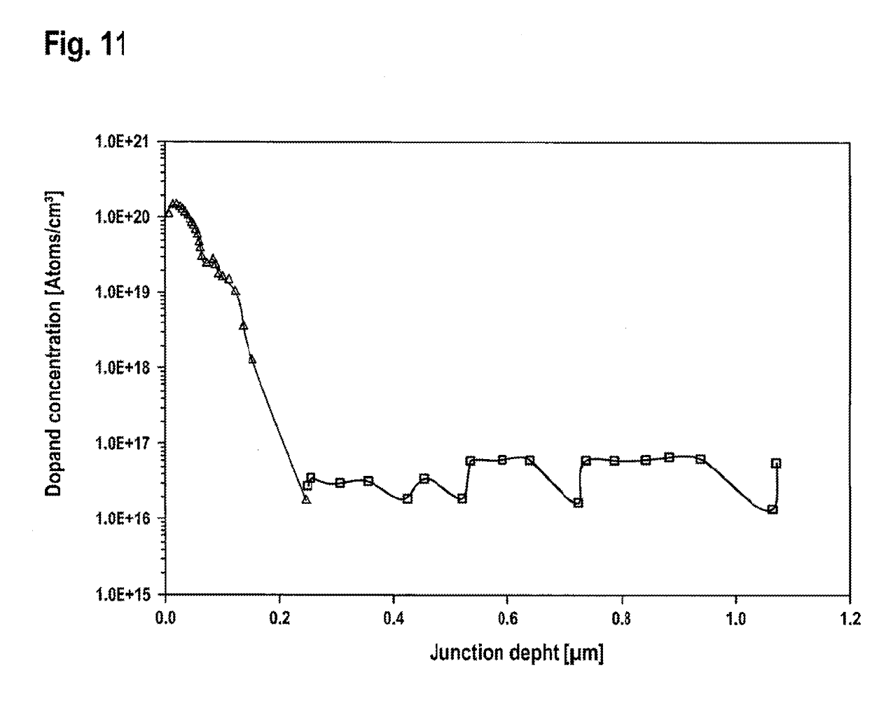

1. Process for the preparation of printable, low-viscosity oxide media in the form of doping media, characterised in that an anhydrous sol-gel-based synthesis is carried out by condensation of alkoxysilanes and/or alkoxyalkylsilanes with symmetrical and asymmetrical carboxylic anhydrides
i. in the presence of boron-containing compounds and/or
ii. in the presence of phosphorus-containing compounds and low-viscosity doping media (doping inks) are prepared by controlled gelling.

2. Process according to claim 1, where the alkoxysilanes and/or alkoxyalkylsilanes used contain individual or different saturated or unsaturated, branched or unbranched, aliphatic, alicyclic or aromatic radicals, which may in turn be functionalised at any desired position of the alkoxide and/or alkyl radical by heteroatoms selected from the group O, N, S, Cl, Br.

3. Process according to claim 1, where the boron-containing compounds are selected from the group boron oxide, boric acid and boric acid esters.

4. Process according to claim 1, where the phosphorus-containing compounds are selected from the group phosphorus(V) oxide, phosphoric acid, polyphosphoric acid, phosphoric acid esters and phosphonic acid esters containing siloxane-functionalised groups in the alpha- and beta-position.

5. Process according to claim 1, characterised in that the carboxylic anhydrides used are anhydrides from the group acetic anhydride, ethyl formate (anhydride of formic and acetic acid), propionic anhydride, succinic anhydride, maleic anhydride, sorbic anhydride, phthalic anhydride and benzoic anhydride.

6. Process according to claim 1, characterised in that the printable oxide media are prepared in the form of doping media based on hybrid sols and/or gels (such as, for example, SiO2-P2O5-B2O3 and SiO3-Al2O3-B2O3), using alcoholates/esters, hydroxides or oxides of aluminium, gallium, germanium, zinc, tin, titanium, zirconium or lead, and mixtures thereof.

7. Process according to claim 5, characterised in that use is made of a solvent selected from the group propanol, isopropanol, butanol, butyl acetate, ethyl acetate, ethylene glycol monobutyl ether, diethyl glycol, diethylene glycol, diethylene glycol monobutyl ether, dipropylene glycol monomethyl ether, individually or in a mixture, as solvent.

8. A method which comprises preparing a handling- and abrasion-resistant layer on silicon wafers using an oxide medium prepared by a process according to claim 1, characterised in that the oxide medium printed on the surface is dried and compacted for vitrification in a temperature range between 50° C. and 750° C., preferably between 50° C. and 500° C., particularly preferably between 50° C. and 400° C., using one or more heating steps to be carried out sequentially (heating by means of a step function) and/or a heating ramp, enabling a handling- and abrasion-resistant layer having a thickness of up to 500 nm to form.

9. Process according to claim 1, characterised in that the stability of the oxide media is improved by addition of “capping agents” selected from the group acetoxytrialkylsilanes, alkoxytrialkylsilanes, halotrialkylsilanes and derivatives thereof.

10. A method which comprises using an oxide medium prepared by a process according to claim 1 as doping medium in the treatment of silicon wafers for photovoltaic, microelectronic, micromechanical and micro-optical applications.

11. A method according to claim 10, characterised in that silicon-doping atoms, such as boron and/or phosphorus, are released from the layers vitrified on the surfaces to the substrate by heat treatment at a temperature in the range between 750° C. and 1100° C., preferably between 850° C. and 1100° C., particularly preferably between 850° C. and 1000° C., thereby influencing the conductivity of the substrate.

12. A method according to claim 11, characterised in that temperature treatment of the layers formed from the printed-on oxide media causes co-diffusion with formation of n- and p-type layers.

13. A method which comprises using an oxide medium prepared by a process according to claim 1 for the production of PERC, PERL, PERT, IBC solar cells and others, where the solar cells have further architecture features, such as MWT, EWT, selective emitter, selective front surface field, selective back surface field and bifaciality.

14. A method which comprises using a low-viscosity oxide medium prepared by a process according to claim 1 for the production of thin, dense glass layers which act as sodium and potassium diffusion barrier in LCD technology as a consequence of thermal treatment, or of corresponding glass layers on the cover glass of a display, consisting of doped SiO₂, which prevent the diffusion of ions from the cover glass into the liquid-crystalline phase.
